(19) United States
(12) Patent Application Publication
(10) Pub. No.: US 2025/0362206 A1
(43) Pub. Date: Nov. 27, 2025

(54) APPROXIMATION ERROR DETECTION DEVICE AND NON-TRANSITORY COMPUTER-READABLE MEDIUM STORING AN APPROXIMATION ERROR DETECTION PROGRAM

(71) Applicant: FANUC CORPORATION, Minamitsuru-gun, Yamanashi (JP)

(72) Inventor: Daijirou KOGA, Yamanashi (JP)

(73) Assignee: FANUC CORPORATION, Minamitsuru-gun, Yamanashi (JP)

(21) Appl. No.: 18/872,739

(22) PCT Filed: Jun. 24, 2022
(86) PCT No.: PCT/JP2022/025418

§ 371 Date: Dec. 6, 2024

(51) Int. Cl. G01M 99/00; G06F 3/14

(52) U.S. Cl. CPC G01M 99/005; G06F 3/14

(57) ABSTRACT

The present invention makes it possible to detect an approximation error amount in approximating and encoding axis-dependent data that depends on the coordinate value of each axis of an industrial machine. An approximation error detection device 1 comprises an approximation error amount detection unit 11 that detects an approximation error amount with an absolute value greater than or equal to a predetermined threshold among approximation error amounts in performing model approximation encoding of axis-dependent data on the basis of a part of the axis-dependent data that depends on the coordinate value of each axis of an industrial machine, and on a linear combination model that approximates the axis-dependent data as a linear combination of data on each axis of the industrial machine.

### TECHNICAL FIELD

The present disclosure relates to an approximation error detection device and an approximation error detection program.

### BACKGROUND ART

Conventionally, industrial machines such as a machine tool and a robot each cause a predetermined control point to move to a predetermined position in accordance with a command value. However, since such industrial machines are subject to errors, the position of the control point often does not conform to the command value. In order to resolve such a decrease in positioning accuracy which would lead to a decrease in machining accuracy, a technique has been proposed which compensates for an error so that the position of a control point conforms to a command value (for example, refer to Patent Document 1). With this technique, by inputting the error amount measured in advance to a control device, the error is compensated based on the compensation amount corresponding to the error amount.

### CITATION LIST

### Patent Document

Patent Document 1: Japanese Unexamined Patent Application, Publication No. 2011-209897

### DISCLOSURE OF THE INVENTION

### Problems to be Solved by the Invention

However, upon compensating for the error, as the number of input points of the error amount inputted to the control device increases, the error can be compensated with higher accuracy. However, since there is an upper limit to the inputtable data size, there is a problem in that the accuracy of error compensation cannot be improved beyond the upper limit of the inputtable data size.

Therefore, it is conceivable to compress the data of the error amount and input the compressed data to the control device. Examples of a technique for compressing data include a data encoding technique and, for example, an entropy encoding technique such as Huffman coding is known. The entropy encoding technique compresses data by utilizing bias in the appearance frequency of values on the data, i.e., the smallness of information entropy.

However, the axis-dependent data depending on the coordinate values of each axis of an industrial machine such as the above-described error amount may have a white noise-like property in which the appearance frequency is uniform as a whole. In this case, since the above-described smallness of information entropy cannot be used, it is difficult to compress data by the entropy encoding.

In this regard, the inventors of the present invention have studied a data encoding technique capable of compressing, through approximating and encoding, axis-dependent data depending on coordinate values of each axis of an industrial machine. Here, when the axis-dependent data is approximated and encoded, an approximation error amount may still remain. The approximation error amount is small in the normal state. However, when the approximation error amount is larger than that in the normal state, there may be an issue at the time of measuring the error amount or at the time of error compensation, and it is not possible to perform the error compensation with high accuracy. However, conventionally, there has been a problem in that the user cannot notice such a decrease in accuracy of error compensation.

The present disclosure has been made in view of the above, and an object of the present disclosure is to provide an approximation error detection device and an approximation error detection program capable of detecting an approximation error when axis-dependent data depending on coordinate values of each axis of an industrial machine is approximated and encoded.

An aspect of the present disclosure is directed to an approximation error detection device that detects an approximation error, the approximation error detection device including an approximation error amount detector that detects, based on a portion of axis-dependent data depending on coordinates of each axis of an industrial machine and a linear combination model that approximates the axis-dependent data as a linear combination of data of each axis of the industrial machine, an approximation error amount having an absolute value equal to or greater than a predetermined value, from among approximation error amounts obtained by performing model approximation encoding on the axis-dependent data.

Another aspect of the present disclosure is directed to an approximation error detection program for detecting an approximation error, the program causing a computer to execute a step of detecting, based on a portion of axis-dependent data depending on coordinates of each axis of an industrial machine and a linear combination model that approximates the axis-dependent data as a linear combination of data of each axis of the industrial machine, an approximation error amount having an absolute value equal to or greater than a predetermined value, from among approximation error amounts obtained by performing model approximation encoding on the axis-dependent data.

According to the present disclosure, it is possible to provide an approximation error detection device and an approximation error detection program capable of detecting an approximation error when axis-dependent data depending on coordinate values of each axis of an industrial machine is approximated and encoded.

### BRIEF DESCRIPTION OF THE DRAWINGS

FIG. 1 is a diagram showing a configuration of an approximation error detection device according to a first embodiment;

FIG. 2 is a diagram showing an example of a text file including only specific characters;

FIG. 3 is a diagram showing an example of data in which the appearance frequency of each value is represented by a specific distribution;

FIG. 4 is a diagram showing data in which the appearance frequency of each value is uniform;

FIG. 5 is a diagram showing each axis error of an X-axis error;

FIG. 6 is a diagram showing each axis error of the Y axis;

FIG. 7 is a diagram showing error amounts at coordinate values (X₂, Y₁);

FIG. 8 is a diagram showing error amounts which cannot be expressed with a linear combination of each axis error;

FIG. 9 is a partially enlarged view of FIG. 8;

FIG. 10 is a diagram showing a bitmap image in which an error map is visualized;

FIG. 11 is a diagram showing an example of axis-dependent data;

FIG. 12 is a diagram showing a linear combination model approximating the axis-dependent data of FIG. 11 as a linear combination of each axis error of an industrial machine;

FIG. 13 is a diagram showing an approximation error amount having a large absolute value;

FIG. 14 is a diagram showing a state in which a structure interferes with an industrial machine at the time of measuring an approximation error amount;

FIG. 15 is a diagram showing a configuration of a data encoding device in a first modification of the approximation error detection device according to the first embodiment;

FIG. 16 is a diagram showing axis-dependent data divided into a plurality of grid regions;

FIG. 17 is a diagram showing an example of divided axis-dependent data;

FIG. 18 is a diagram showing a configuration of a data encoding device in a second modification of the approximation error detection device according to the first embodiment;

FIG. 19 is a flowchart showing a procedure of dividing axis-dependent data by a dynamic programming processor;

FIG. 20 is a diagram showing a divided section before expanding data of each axis (each axis error) by one row in the X positive direction;

FIG. 21 is a diagram showing a divided section after expanding data of each axis (each axis error) by one row in the X positive direction;

FIG. 22 is a diagram showing a configuration of a data encoding device in a third modification of the approximation error detection device according to the first embodiment;

FIG. 23 is a flowchart showing a procedure of learning processing by a machine learning device;

FIG. 24 is a diagram showing a configuration of an approximation error detection device according to a second embodiment;

FIG. 25 is a diagram showing an example of numerical value display of an approximation error amount when a threshold is set to 0;

FIG. 26 is a diagram showing a first example of numerical value display of the approximation error amount when the absolute value of the threshold is greater than 0;

FIG. 27 is a diagram showing a second example of numerical value display of an approximation error amount when the absolute value of a threshold is greater than 0;

FIG. 28 is a diagram showing a configuration of an approximation error detection device according to a third embodiment;

FIG. 29 is a diagram showing an example of graphic display of an approximation error amount when a threshold is set to 0;

FIG. 30 is a diagram showing a first example of graphic display of the approximation error amount when the absolute value of a threshold is greater than 0; and

FIG. 31 is a diagram showing a second example of graphic display of the approximation error amount when the absolute value of the threshold is greater than 0.

### PREFERRED MODE FOR CARRYING OUT THE INVENTION

Hereinafter, embodiments of the present disclosure will be described in detail with reference to the drawings. In the description of the second and subsequent embodiments, the description of the configuration common to the first embodiment will be omitted as appropriate.

### FIRST EMBODIMENT

An approximation error detection device according to a first embodiment is a device capable of detecting an approximation error when axis-dependent data depending on coordinate values of each axis of an industrial machine is approximated and encoded. As described above, the axis-dependent data depending on coordinate values of each axis of an industrial machine is difficult to compress by a conventional entropy encoding technique. On the contrary, the inventor of the present invention has studied a data encoding technique capable of compressing, through approximating and encoding, the axis-dependent data depending on coordinate values of each axis of an industrial machine. However, when the axis-dependent data is approximated and encoded, an approximation error amount may still remain. When the approximation error amount is larger than that in the normal state, there may be an issue at the time of measuring the error amount or at the time of error compensation, and it is not possible to perform the error compensation with high accuracy. In view of the above, an approximation error detection device according to embodiments of the present application is capable of detecting such an approximation error, whereby the user can notice such a decrease in accuracy of error compensation.

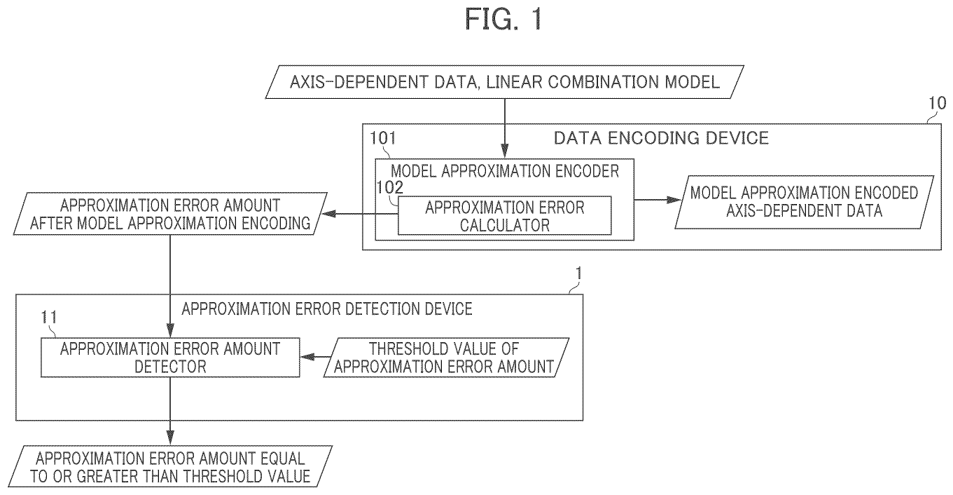

FIG. 1 is a diagram showing a configuration of an approximation error detection device 1 according to a first embodiment. As shown in FIG. 1, the approximation error detection device 1 according to the present embodiment includes an approximation error amount detector 11. The approximation error detection device 1 includes a computer including, for example, memory such as ROM (read only memory) and RAM (random access memory), a CPU (control processing unit), an operation unit such as a keyboard, a display, and a communication controller, which are connected to each other via a bus. The functions and operations of the functional units described later are achieved by the cooperation of a CPU and memory, which are mounted on the computer, and control programs stored in the memory.

The approximation error detection device 1 may be provided in, for example, a numerical control device (CNC: Computerized Numerical Control) or a robot control device corresponding to a control device of a machine tool or an industrial machine such as a robot. Alternatively, the approximation error detection device 1 may be provided in an external computer or the like so as to be able to communicate with these control devices.

Before describing the configuration of the approximation error detection device 1 according to the present embodiment, a data encoding device 10 that generates an approximation error amount after model approximation encoding inputted to the approximation error detection device 1 according to the present embodiment will be described in detail.

The data encoding device 10 is a data encoding device capable of encoding and compressing axis-dependent data depending on coordinate values of each axis of an industrial machine such as an error amount or the like for use in error compensation of each axis of the industrial machine. Since the axis-dependent data depending on the coordinate values of each axis of the industrial machine may have a white noise-like property in which the appearance frequency as a whole is uniform, it is difficult to compress the data by the conventional entropy encoding technique using the bias of the appearance frequency of the values on the data, that is, the smallness of the information entropy. On the contrary, the data encoding device 10 according to the present embodiment is capable of encoding and compressing axis-dependent data depending on coordinate values of each axis of an industrial machine.

As shown in FIG. 1, the data encoding device 10 includes a model approximation encoder 101. The model approximation encoder 101 generates encoded axis-dependent data obtained by encoding the axis-dependent data based on axis-dependent data and a linear combination model. In describing the configuration of the data encoding device 10, first, a conventional data encoding technique will be described.

As a data encoding technique, for example, an entropy encoding technique such as Huffman coding is conventionally known. The entropy encoding technique compresses data by utilizing bias in the appearance frequency of values on the data, i.e., the smallness of information entropy.

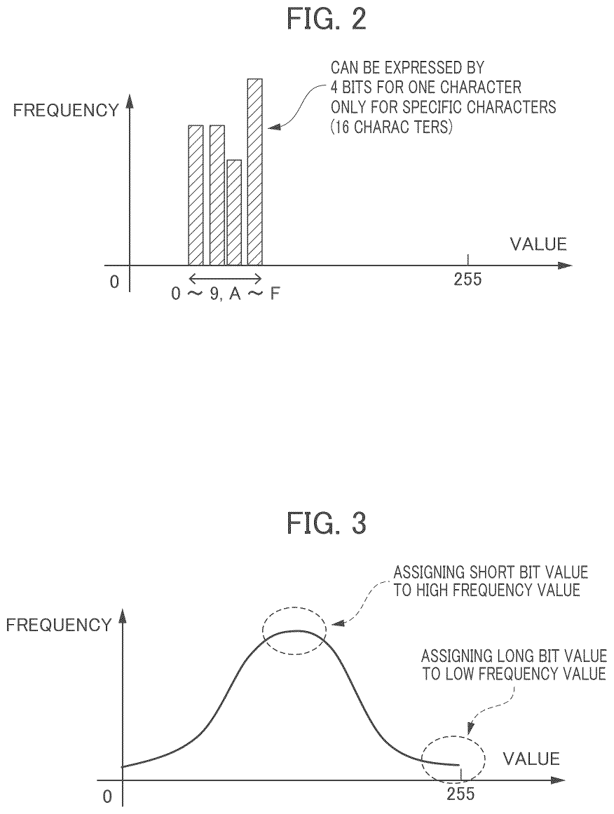

Herein, FIG. 2 is a diagram showing an example of a text file including only specific characters. Further, FIG. 3 is a diagram showing an example of data in which the appearance frequency of each value is represented by a specific distribution. In each of FIGS. 2 and 3, the horizontal axis indicates a bit value, and the vertical axis indicates an appearance frequency of each value. As shown in FIG. 2, for example, a text file including only the 16 characters of 0 to 9 and A to F as specific characters normally requires 8 bits for expression of one character, but can be expressed by 4 bits at most for expression of one character by entropy encoding, so that data can be compressed in about half. Further, data having a non-uniform appearance frequency as shown in FIG. 3 can be compressed by assigning a short bit value to a high frequency value and assigning a long bit value to a low frequency value by entropy encoding.

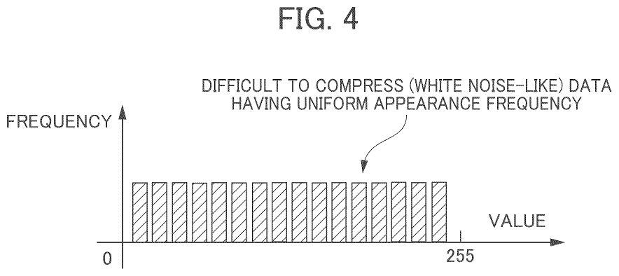

On the other hand, FIG. 4 is a diagram showing data in which the appearance frequency of each value is uniform. Similarly to FIGS. 2 and 3, in FIG. 4, the horizontal axis indicates a bit value, and the vertical axis indicates the appearance frequency of each value. Since white noise-like data having a uniform appearance frequency as shown in FIG. 4 cannot utilize the above-described smallness of information entropy, it is difficult to compress the data by entropy encoding.

By the way, examples of the static error compensation of each axis of the industrial machine include pitch error compensation, straightness error compensation, and three-dimensional error compensation. The pitch error compensation is compensation of an error in a direction along the axial direction. The straightness error compensation is compensation of an error in a direction orthogonal to the axial direction. The three-dimensional error compensation is compensation of a three-dimensional spatial error. These error compensations are executed by inputting the amount of error (hereinafter, referred to as each axis error) measured for each coordinate value of each axis to the control device for the number of axes. As the number of input points increases, the accuracy of error compensation improves, but there is an upper limit to the size of data that can be inputted.

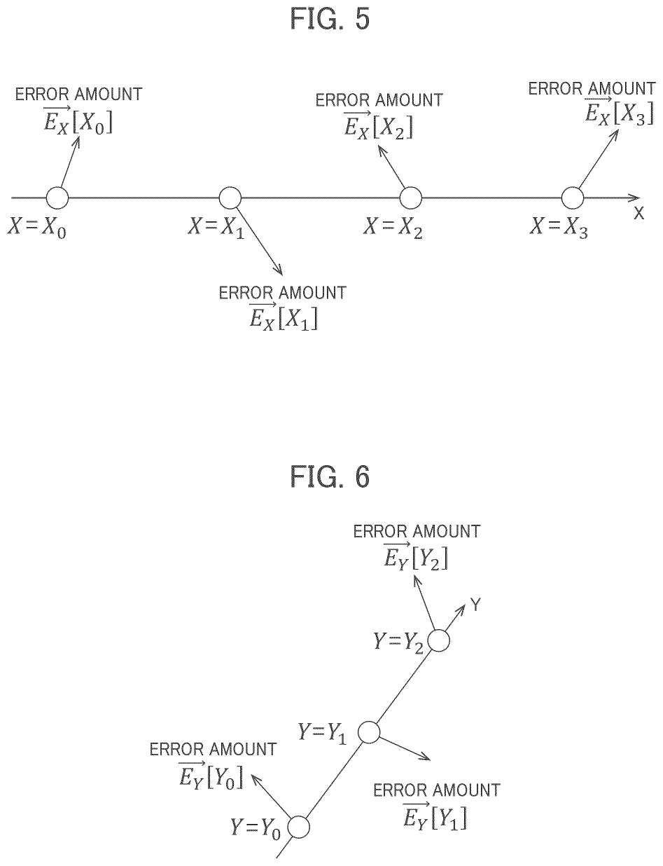

FIG. 5 is a diagram showing each axis error of the X-axis. Each axis error of the X axis is an error amount of each coordinate value measured when only the X axis is moved in a state where the Y axis and the Z axis are fixed. As shown in FIG. 5, the error amounts of the coordinate values X₀, X₁, X₂, and X₃ are displayed as vectors having different sizes and directions.

FIG. 6 is a diagram showing each axis error of the Y axis. Each axis error of the Y axis is an error amount of each coordinate value measured when only the Y axis is moved in a state where the X axis and the Z axis are fixed. As shown in FIG. 6, the error amounts of the coordinate values Y₀, Y₁, and Y₂ are displayed as vectors having different sizes and directions.

Here, in the error compensation of each axis, it is assumed that each axis error is linearly independent. That is, assuming that the error amount in each of the coordinate values X₁ . . . X_{L} (vector E[X¹] . . . [X^{L}]) is a linear combination of each axis error, the error amount is expressed by the following Expression (1).

$$\begin{matrix}[ Expression 1 ] & \\ \vec{E} [ {X}^{1} ] … [ {X}^{L} ] := {\sum }_{l = 1}^{L} \vec{{E}_{{X}^{l}}} [ {X}^{l} ] & Expression ( 1 )\end{matrix}$$

In Expression (1) above, L represents the number of target axes subjected to error compensation. Further, X¹ represents the first compensation target axis.

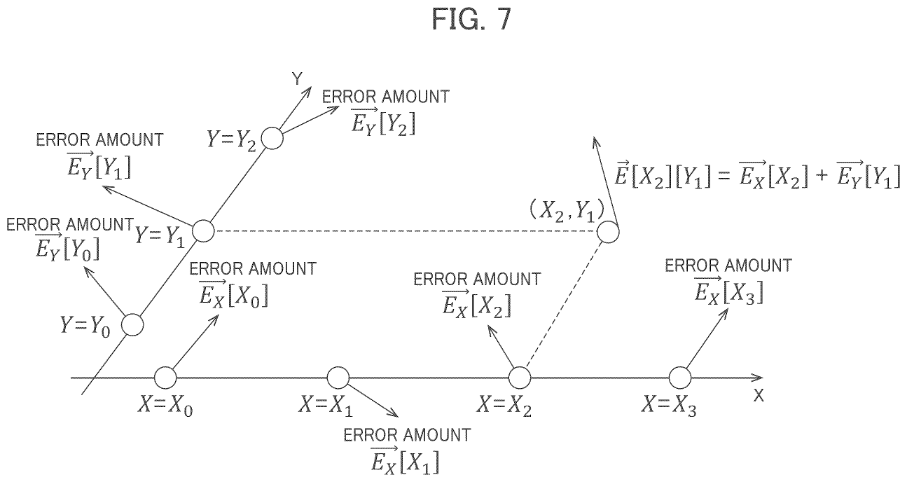

There are many situations where the above Expression (1) based on the above assumption holds, and conventionally, error compensation for each axis is widely used. For example, FIG. 7 is a diagram showing an error amount in the coordinate value (X₂, Y¹). As shown in FIG. 7, the error amount (vector E [X₂][Y¹]) in the coordinate value (X₂, Y¹) can be regarded as a linear combination of the error amount (vector E_{X}[X²]) in the coordinate value X₂ and the error amount (vector E_{Y}[Y¹]) in the coordinate value Y₁, and is represented by the following Expression (2).

$$\begin{matrix}[ Expression 2 ] & \\ \vec{E} [ {X}_{2} ] [ {Y}_{1} ] = \vec{{E}_{X}} [ {X}_{2} ] + \vec{{E}_{Y}} [ {Y}_{1} ] & Expression ( 2 )\end{matrix}$$

However, when viewed as a whole, the appearance frequency of the value in each axis error (vector E_{X}[X], vector E_{Y}[Y]) or the appearance frequency of the value in the error amount (vector E[X][Y]) may be uniform in a white noise-like manner. In this case, it is difficult to compress the data by the conventional entropy encoding technique using the bias of the appearance frequency of the values on the data, that is, the smallness of information entropy.

In addition, each axis error may not be linearly independent, or the error amount (vector E[X¹] . . . [X^{L}]) may be determined by correlation between a plurality of axes. That is, the error amount (vector E[X¹] . . . [X^{L}]) includes the correlation term (vector δ[X¹] . . . [X^{L}]) as represented by the following Expression (3), and may not be represented by a linear combination of each axis error.

$$\begin{matrix}[ Expression 3 ] & \\ \vec{E} [ {X}^{1} ] … [ {X}^{L} ] := {\sum }_{l = 1}^{L} \vec{{E}_{{X}^{l}}} [ {X}^{l} ] + \vec{δ} [ {X}^{1} ] … [ {X}^{L} ] & Expression ( 3 )\end{matrix}$$

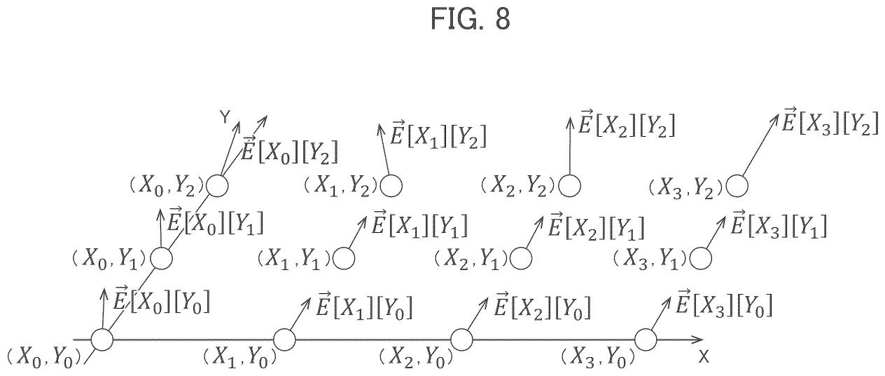

FIG. 8 is a diagram showing error amounts which cannot be expressed with a linear combination of each axis error. As shown in FIG. 8, when each axis error is not linear independent, the error amount (vector E[X¹] . . . [X^{L}]) needs to be an error amount including a correlation term (vector δ[X¹] . . . [X^{L}]) represented by the above-described Expression (3), instead of the error amount represented by the above-described Expression (1). In this case, since the error amount (hereinafter, referred to as a spatial error) is inputted to a control device and compensated for each space having a correlation with the error amount, it is called error compensation for each space.

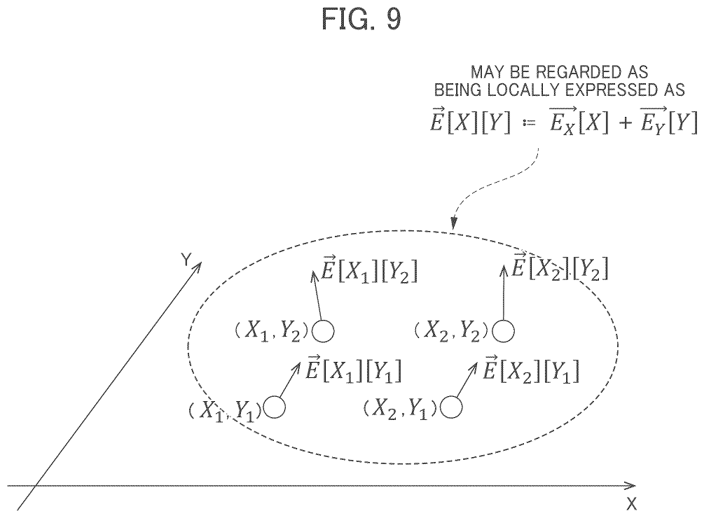

Here, the present inventor has found that the spatial error cannot be expressed as a linear combination of each axis error as a whole, but can be locally regarded as a linear combination of each axis error as in the case of each axis error. For example, FIG. 9 is a partial enlarged view of FIG. 8. However, in the local region surrounded by the broken line in FIG. 9, the above correlation term (vector δ[X¹] . . . [X^{L}]) can be regarded as 0, and the spatial error can be represented as a linear combination of each axis error. That is, the spatial error (vector E[X][Y]) is represented by the sum of each axis error (vector E_{X}[X]) and each axis error (vector E_{Y}[Y]) as shown in the following Expression (4). This indicates that the spatial error (vector E[X][Y]) can be approximated as a linear combination of an error amount (vector E_{X}[X]) in one row in the X-axis direction and an error amount (vector E_{Y}[Y]) in one row in the Y-axis direction, among data of each axis (each axis error) on a plurality of coordinate points in a grid manner. It should be noted that the examples of the local region include a central region of a movable range of the industrial machine.

$$\begin{matrix}[ Expression 4 ] & \\ \vec{E} [ X ] [ Y ] := \vec{{E}_{X}} [ X ] + \vec{{E}_{Y}} [ Y ] & Expression ( 4 )\end{matrix}$$

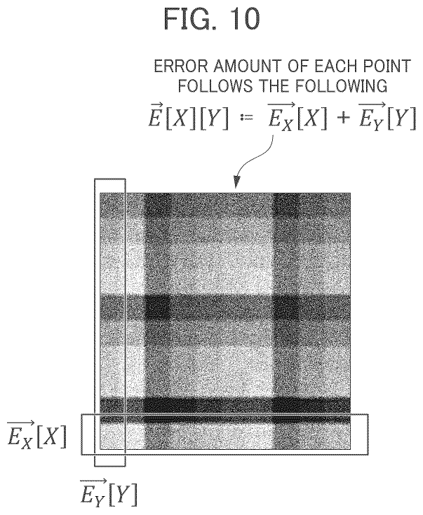

However, when viewed as a whole, the appearance frequency of values in the spatial error (vector E[X][Y]) may be uniform in a white noise-like manner, and thus it is difficult to compress the data by a conventional entropy encoding technique using the smallness of information entropy. For example, FIG. 10 is a diagram showing a bitmap image visualizing an error map in a case where the target axes of error compensation are the two axes of the X axis and the Y axis, and RGB values of each pixel correspond to the error amount vector E. Further, the error amount (vector E[X][Y]) of each pixel is represented by the sum of the vector E_{X}[X] and the vector E_{Y}[Y] in accordance with Expression (4). For example, in a case where the number of pixels of the bitmap image shown in FIG. 10 is 10×10 and 374 bytes, when the bitmap image is encoded by ZIP compression, which is a typical entropy encoding technique, 393 bytes are obtained. As described above, it can be seen that the conventionally known entropy encoding has no compression effect, and in some cases, the data size increases, resulting in an inverse effect.

In view of the above, in the data encoding device 10, even for axis-dependent data depending on coordinate values of each axis of an industrial machine such as an error amount or the like for use in error compensation of each axis of the industrial machine, the property is utilized which can be locally regarded as a linear combination of each axis error as represented by the above-described Expression (1). As a result, it is possible for the data encoding device 10 to encode and compress the axis-dependent data, which has been difficult in the related art.

Referring back to FIG. 1, the data encoding device 10 includes a computer including, for example, memory such as ROM (read only memory) and RAM (random access memory), a CPU (control processing unit), an operation unit such as a keyboard, a display, and a communication controller, which are connected to each other via a bus. The functions and operations of the functional units described later are achieved by the cooperation of the CPU and memory, which are mounted on the computer, and control programs stored in the memory.

The data encoding device 10 according to the present embodiment may be provided in, for example, a numerical control device (CNC: Computerized Numerical Control) or a robot control device corresponding to a control device of a machine tool or an industrial machine such as a robot. Alternatively, the data encoding device 10 may be provided in an external computer or the like so as to be able to communicate with these control devices.

The model approximation encoder 101 included in the data encoding device 10 generates encoded axis-dependent data obtained by encoding the axis-dependent data based on a portion of the axis-dependent data depending on coordinate values of each axis of the industrial machine and a linear combination model that approximates the axis-dependent data as a linear combination of data of each axis (each axis error) of the industrial machine. The axis-dependent data is inputted from, for example, the above-described control device or the like. Further, the linear combination model is stored in, for example, the storage of the data encoding device 10.

Here, each axis of the industrial machine indicates, for example, each axis of the machine tool, that is, the X axis, the Y axis, and the Z axis. Further, examples of the axis-dependent data include the error amount for use in the error compensation of each axis of the industrial machine and, for example, an installation error amount of a relatively large workpiece whose displacement is different for each coordinate value due to the influence of deflection due to its own weight. Each of the error amount and the installation error amount of the workpiece is data depending on coordinate values of each axis of the industrial machine.

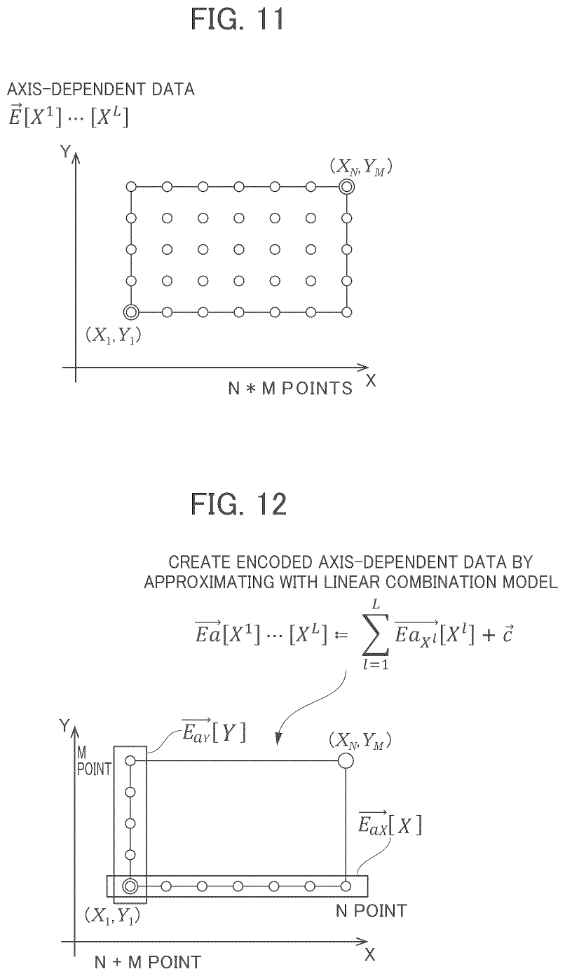

Hereinafter, the model approximation encoding using a linear combination model by the model approximation encoder 101 will be described in detail with reference to FIGS. 11 and 12.

FIG. 11 is a diagram showing an example of axis-dependent data. In the example shown in FIG. 11, axis-dependent data in a case where two axes, i.e., the X-axis and the Y-axis, are used as target axes for error compensation and the like is shown. The axis-dependent data shown in FIG. 11 is axis-dependent data of a specific local region in axis-dependent data in which there is no bias in the appearance frequency of values on the data as a whole in terms of, for example, error amounts of each axis of the industrial machine, and is axis-dependent data that can be approximated by a linear combination model described later. The example of the axis-dependent data shown in FIG. 11 includes data of each axis (each axis error) of N×M points in total.

FIG. 12 is a diagram showing a linear combination model approximating the axis-dependent data of FIG. 11 as a linear combination of each axis error of an industrial machine. As described above, even when the error amount (vector E[X¹] . . . [X^{L}]) conforms to the model represented by Expression (3) and the influence of the correlation term (vector δ[X¹] . . . [X^{L})) is considered to be strong as a whole, it is considered that a region that can be approximated by the linear combination model represented by the mathematical Expression (1) locally exists. For such a region that can be approximated, as shown in FIG. 12, the error amount can be expressed by an approximation model (vector Ea[X¹] . . . [X^{L}]) as a linear combination model represented by the following Expression (5). That is, the error amount can be approximated as a linear combination of an error amount (vector Ea_{X}[X]) in one row in the X-axis direction and an error amount (vector Ea_{Y}[Y]) in one row in the Y-axis direction. In the example shown in FIG. 12, data of each axis (each axis error) after approximation becomes N+M points in total, and it can be seen that the axis-dependent data can be compressed.

$$\begin{matrix}[ Expression 5 ] & \\ \vec{Ea} [ {X}^{1} ] … [ {X}^{L} ] := {\sum }_{l = 1}^{L} \vec{{Ea}_{{X}^{l}}} [ {X}^{l} ] + \vec{c} & Expression ( 5 )\end{matrix}$$

In Expression (5), X¹ and X^{L} are represented by Expression (6) below, and a vector c is defined as an average value as represented by Expression (7) below. The vector Ea_{X}¹[X¹] is expressed by the following Expression (8). Further, L represents the number of target axes subjected to error compensation, X¹ represents the first compensation target axis, and N¹ represents the error amount point of the first compensation target axis.

$$\begin{matrix}[ Expression 6 ] & \\ {X}^{1} := [ {X}_{1}^{1} , … , {X}_{{N}^{1}}^{1} ] … {X}^{L} := [ {X}_{1}^{L} , … , {X}_{{N}^{L}}^{L} ] & Expression ( 6 )\end{matrix}$$

$$\begin{matrix}[ Expression 7 ] & \\ \vec{c} := \frac{1}{{\sum }_{l = 1}^{L} {N}^{l}} {\sum }_{{X}^{1} = 1}^{{N}^{1}} … {\sum }_{{X}^{L} = 1}^{{N}^{L}} ( \vec{E} [ {X}^{1} ] … [ {X}^{L} ] - {\sum }_{l = 1}^{L} \vec{{Ea}_{{X}^{l}}} [ {X}^{l} ] ) & Expression ( 7 )\end{matrix}$$

$$\begin{matrix}[ Expression 8 ] & \\ \vec{{Ea}_{{X}^{l}}} [ {X}^{l} ] := \vec{E} [ {x}^{1} ] … [ {X}^{l} ] … [ {x}^{L} ] & Expression ( 8 )\end{matrix}$$

$$provided that {X}^{p} is any value that satisfies$$

$$( {X}_{1}^{p} \leq {x}^{p} \leq {X}_{{N}^{p}}^{p} ) and common in each \vec{{Ea}_{{X}^{l}}} [ {X}^{l} ]$$

In Expression (8), while X represents a one-dimensional axial space, x represents an element belonging to the space. The symbol p is any value from 1 to L. For example, x³ indicates a certain value that can be taken by the axis X³.

When the vector c is defined as in the above Expression (7), the approximation model (vector Ea[X₁] . . . [X_{L}]) as the linear combination model becomes a maximum likelihood estimation model that minimizes the evaluation function J expressed by the following Expression (9). That is, the evaluation function J is expressed as the sum of squares of the difference between the original error amount before approximation (vector E[X¹] . . . [X^{L}]) and the error amount after approximation (vector Ea[X¹] . . . [X^{L}]), as represented by the following Expression (9), and the approximation model (vector Ea[X₁] . . . [X_{L}]) as the linear combination model is determined so that the evaluation function J is minimized. The approximation model as the linear combination model thus determined is stored in, for example, the storage of the data encoding device 10, and is used for model approximation encoding by the model approximation encoder 101.

$$\begin{matrix}[ Expression 9 ] & \\ J := {\sum }_{{X}^{1} = 1}^{{N}^{1}} … {\sum }_{{X}^{L} = 1}^{{N}^{L}} ( \vec{E} [ {X}^{1} ] … [ {X}^{L} ] - \vec{Ea} [ {X}^{1} ] … [ {X}^{L} ] ) \cdot ( \vec{E} [ {X}^{1} ] … [ {X}^{L} ] - \vec{Ea} [ {X}^{1} ] … [ {X}^{L} ] ) & Expression ( 9 )\end{matrix}$$

As described above, in the data encoding device 10, it is possible to encode and compress the axis-dependent data, which has been conventionally difficult to compress, by approximating a portion of the axis-dependent data as a linear combination of each axis data (each axis error). Therefore, it is possible to increase data such as the error amount that is inputtable to the control device or the like of the industrial machine without increasing the storage capacity, and it is possible to more accurately compensate for the error of the industrial machine.

With reference to FIG. 1 again, the data encoding device 10 includes an approximation error calculator 102 that calculates an approximation error amount after model approximation encoding. The approximation error calculator 102 is provided in the model approximation encoder 101, and calculates an approximation error amount according to model approximation encoding of the axis-dependent data.

As described above, when the error amount is expressed by the approximation model (vector Ea[X¹] . . . [X^{L}]) as the linear combination model expressed by the above-described Expression (5), the approximation errors (vectors γ[X¹] . . . [X^{L}]) are expressed by the following Expression (10).

$$\begin{matrix}[ Expression 10 ] & \\ \vec{γ} [ {X}^{1} ] … [ {X}^{L} ] := \vec{E} [ {X}^{1} ] … [ {X}^{L} ] - \vec{Ea} [ {X}^{1} ] … [ {X}^{L} ] & Expression ( 10 )\end{matrix}$$

In Expression (10), vectors E[X¹] . . . [X^{L}] are original error amounts before model approximation, and vectors Ea[X¹] . . . [X^{L}] are error amounts after model approximation. It can be seen from Expression (10) that these differences are approximation errors (vectors γ[X¹] . . . [X^{L}]).

Here, since the approximation model (vector Ea[X¹] . . . [X^{L}]) is the maximum likelihood estimation model, the approximation errors (vectors γ[X¹] . . . [X^{L}]) are minimized and become only very small values. In addition, only small values of the approximation errors (vectors γ[X][Y]) are unevenly distributed, and the frequency distribution of the values is also unevenly distributed. Therefore, data can be compressed by encoding the approximation errors (vectors γ[X¹] . . . [X^{L}]).

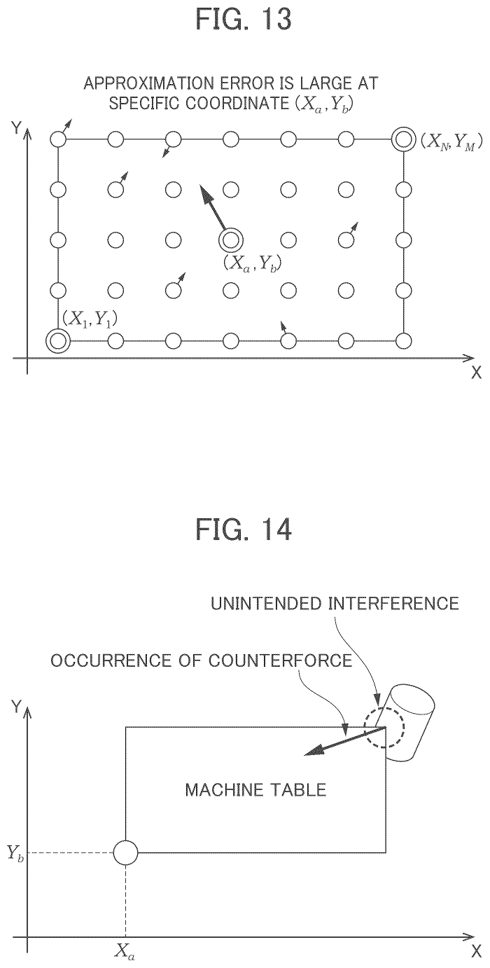

Therefore, the approximation error amount after the model approximation encoding by the model approximation encoder 101 is basically well approximated by the linear combination of data of each axis. However, the approximation error amount may still remain in model approximation encoding by the model approximation encoding by the model approximation encoder 101. Here, FIG. 13 is a diagram showing an approximation error amount having a large absolute value. As shown in FIG. 13, the approximation error amount may be large at a specific coordinate (Xa, Xb). As a cause of this, for example, a case can be exemplified where a measurement method of the approximation error amount is wrong and is not appropriate.

FIG. 14 is a diagram showing a state in which a structure interferes with an industrial machine at the time of measuring an approximation error amount. As shown in FIG. 14, when an approximation error amount of a specific coordinate value is measured, a machine structure, for example, a machine table constituting an industrial machine, may interfere with an unintended structure. In this case, the approximation error amount cannot be accurately measured by the counterforce due to the interference. Further, when the interference is eliminated by, for example, the structure falling down during the movement after the measurement, as a result, only the measurement result of the specific coordinate becomes incorrect, and the approximation error amount may increase.

As described above, when the error compensation is performed using an inappropriate approximation error amount, the accuracy of the error compensation decreases. However, conventionally, there is no measure for prompting the user to notice the decrease in the accuracy of the error compensation. In view of the above, the approximation error amount detector 11 of the approximation error detection device 1 according to the present embodiment has a function of detecting the approximation error amount, whereby the user can notice a decrease in the accuracy of error compensation.

Specifically, the approximation error amount detector 11 detects, based on a portion of axis-dependent data depending on coordinate values of each axis of an industrial machine and a linear combination model that approximates the axis-dependent data as a linear combination of data of each axis of the industrial machine, an approximation error amount having an absolute value equal to or greater than a predetermined threshold value, from among approximation error amounts obtained by performing model approximation encoding on the axis-dependent data. The approximation error amount detected by the approximation error amount detector 11 is outputted to the outside or the like. With such a configuration, the user of the industrial machine can notice that the approximation error amount after the model approximation encoding is equal to or larger than the predetermined threshold.

In addition, the approximation error amount after the model approximation encoding when the axis-dependent data is subjected to the model approximation encoding is generated by the model approximation encoder 101 of the data encoding device 10 described above, and inputted to the approximation error amount detector 11. In addition, the threshold value of the approximation error amount is set to an appropriate value based on the approximation error amount in the normal state by performing a test or the like in advance, and is stored in storage or the like of the approximation error detection device 1, and is acquired from the storage. For example, 0 may be set as the predetermined threshold, and in this case, all approximation error amounts are detected.

According to the present embodiment, the following advantageous effects are achieved.

The approximation error detection device 1 according to the present embodiment includes the approximation error amount detector 11 that detects, based on a portion of axis-dependent data depending on coordinate values of each axis of an industrial machine and a linear combination model that approximates the axis-dependent data as a linear combination of data of each axis of the industrial machine, an approximation error amount having an absolute value equal to or greater than a predetermined threshold value, from among approximation error amounts obtained by performing model approximation encoding on the axis-dependent data. With such a configuration, it is possible to detect an approximation error amount larger than that in the normal state, from among approximation error amounts obtained by approximating and encoding axis-dependent data depending on coordinate values of each axis of the industrial machine. Therefore, the user of the industrial machine can notice that the approximation error amount after the model approximate encoding is equal to or larger than the predetermined threshold value, and can take measures to eliminate some problem occurring at the time of measurement of the approximation error amount or at the time of error compensation, and can perform the appropriate error compensation.

### Modification Example

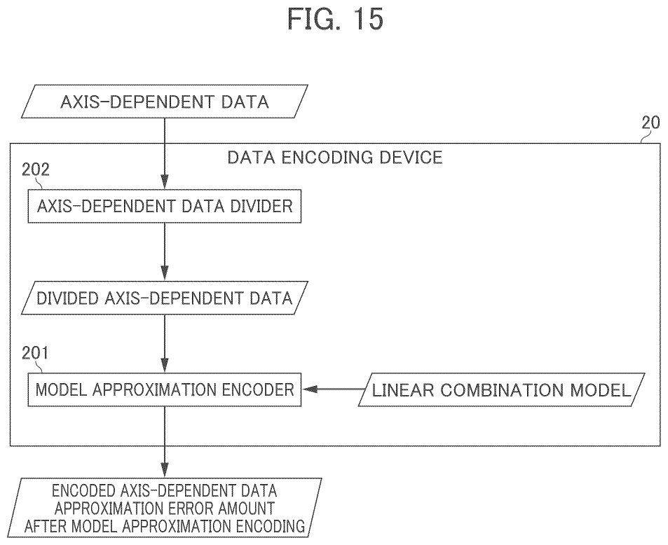

A modification example in which the configuration of the data encoding device is different from that of the approximation error detection device 1 according to the first embodiment will be described. FIG. 15 is a diagram showing a configuration of a data encoding device 20 in a first modification example of the approximation error detection device 1 according to the first embodiment. As shown in FIG. 15, the data encoding device 20 of the first modification example differs from the data encoding device 10 described above in that the data encoding device 20 includes an axis-dependent data divider 202. In addition, the model approximation encoder 201 differs from the model approximation encoder 101 described above in that the model approximation encoder 201 executes model approximation encoding based on divided axis-dependent data generated by dividing the axis-dependent data into a plurality of pieces of data and the linear combination model described above. The configurations of the data encoding device 20 other than these differences are the same as those of the data encoding device 10.

The above-described data encoding device 10 performs model approximation encoding of a linear combination model on the assumption that a portion of axis-dependent data having a uniform appearance frequency in a white noise-like manner as a whole can be regarded as a linear combination of data of each axis (each axis error). On the other hand, the data encoding device 20 actively divides the axis-dependent data into a plurality of regions to generate a plurality of regions that can be regarded as the linear combination of data of each axis (each axis error), thereby enabling the execution of the model approximation encoding of the linear combination model more reliably.

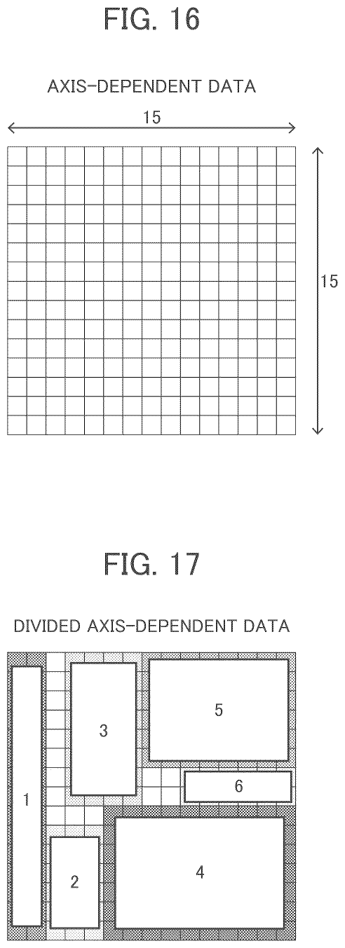

The axis-dependent data divider 202 divides the axis-dependent data to generate a plurality of divided axis-dependent data. Here, FIG. 16 is a diagram showing axis-dependent data divided into a plurality of grid regions. As shown in FIG. 16, the axis-dependent data inputted to the data encoding device 20 is divided into a plurality of grid regions according to data of each axis (each axis error) on each coordinate value, for example. In the example shown in FIG. 16, the axis-dependent data is divided into a grid of 15×15=225 points. The axis-dependent data divider 202 divides the axis-dependent data into a plurality of sections based on the grid, for example.

The method of dividing the axis-dependent data by the axis-dependent data divider 202 is not particularly limited, but it is preferable to divide the axis-dependent data so as to generate a plurality of regions that can be regarded as the linear combination of data of each axis (each axis error). In particular, it is preferable that the axis-dependent data divider 202 divides the axis-dependent data into a plurality of regions that can be best approximated (compressed).

FIG. 17 is a diagram showing an example of divided axis-dependent data. In the example shown in FIG. 17, the axis-dependent data inputted to the data encoding device 20 is divided into the five sections 1 to 5 by the axis-dependent data divider 202. That is, the respective data in the respective regions of the five divided sections 1 to 5 correspond to the divided axis-dependent data, and each of the divided axis-dependent data can be regarded as a linear combination of data of each axis (each axis error), and the model approximation encoding of the linear combination model by the model approximation encoder 201 described later is possible. On the other hand, outside these five divided sections 1 to 5, the axis-dependent data cannot be regarded as a linear combination of data of each axis (each axis error), and model approximation encoding of the linear combination model is impossible.

The model approximation encoder 201 generates encoded axis-dependent data based on the plurality of divided axis-dependent data and the linear combination model. As described above, in each region of the plurality of divided sections 1 to 5, the axis-dependent data can be regarded as a linear combination of data of each axis (each axis error). Therefore, the model approximation encoder 201 performs model approximation encoding of the linear combination model on each of the divided axis-dependent data to generate the encoded axis-dependent data that are model-approximated and compressed.

Although not shown in FIG. 15, the model approximation encoder 201 includes an approximation error calculator similarly to the model approximation encoder 101 described above. Therefore, the model approximation encoder 201 generates and outputs the approximation error amount after the model approximation encoding.

As described above, according to the data encoding device 20, by actively dividing the axis-dependent data into a plurality of regions, it is possible to generate each of the plurality of regions that can be regarded as a linear combination of data of each axis (each axis error), and by performing the model approximation encoding of the linear combination model for each region, it is possible to more reliably compress the axis-dependent data, which has been difficult to compress conventionally.

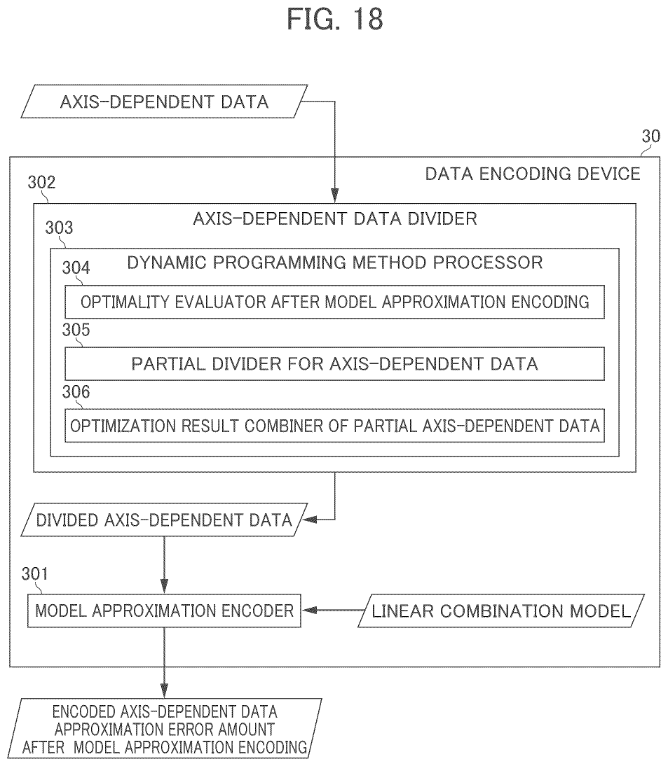

FIG. 18 is a diagram showing the configuration of a data encoding device 30 in a second modification example of the approximation error detection device according to the first embodiment. As shown in FIG. 18, the data encoding device 30 differs from the data encoding device 20 in that the configuration of the axis-dependent data divider 302 differs from that of the axis-dependent data divider 202 described above. The configurations of the data encoding device 30 other than this difference are the same as those of the data encoding device 20.

In the above-described data encoding device 20, the method of dividing the axis-dependent data is not particularly limited, but in the data encoding device 30, the axis-dependent data is divided using a dynamic programming method. That is, by using the dynamic programming method, the optimal division of the axis-dependent data can be executed, and the axis-dependent data can be best approximated and compressed.

As shown in FIG. 18, the axis-dependent data divider 302 includes a dynamic programming processor 303. The dynamic programming processor 303 generates optimal divided axis-dependent data by executing the dynamic programming method. Specifically, the dynamic programming processor 303 includes, as functional units for executing the dynamic programming method, an optimality evaluator 304 after model approximation encoding, a partial divider 305 of the axis-dependent data, and an optimization result combiner 306 of the partial axis-dependent data.

Here, the dynamic programming method executed by the dynamic programming processor 303 will be described in detail.

The dynamic programming method is a generic algorithm for solving optimized problems. The dynamic programming method is an algorithm having the following two features. The first feature is to solve recursively. That is, the first feature is characterized in that a problem is divided into partial problems of a small scale, the partial problems are recursively optimized, and the optimization results of the partial problems are combined to obtain a solution of the original problem of a larger scale. The second feature is that the processing load can be reduced by recording the optimization results. That is, the second feature is characterized in that, although the same problems may appear many times in the process of recursively solving the problems, in order to omit the calculation of a problem which has been solved, the optimization result of the problem which has been solved once is recorded and reused.

Therefore, the dynamic programming processor 303 includes an optimality evaluator 304 after model approximation encoding as a means for evaluating the optimality of the result. That is, the optimality evaluator 304 after the model approximation encoding evaluates the optimality of the encoded axis-dependent data. The evaluation of the optimality of the encoded axis-dependent data can be performed based on, for example, whether an approximation error amount after the model approximation encoding is within a predetermined constraint tolerance. In addition, as described above, the approximation error amount after the model approximation encoding is a difference between the original error amount before the model approximation encoding and the error amount after the model approximation encoding. The constraint tolerance may be, for example, an allowable approximation error value or an allowable number of points of data exceeding the allowable approximation error value.

In addition, the dynamic programming processor 303 according to the present embodiment includes the partial divider 305 of axis-dependent data as a means for dividing a problem into partial problems. The partial divider 305 of the axis-dependent data divides the axis-dependent data into a plurality of portions to generate partial axis-dependent data. For example, the partial divider 305 of the axis-dependent data divides the axis-dependent data into predetermined designated sections in accordance with a predetermined division criterion stored in advance, and reduces the resultant data by one point in each of the positive direction and the negative direction of each axis such as the X axis and the Y axis to optimize the resultant data, thereby obtaining a plurality of portions of the axis-dependent data. The division of the axis-dependent data by the partial divider 305 of the axis-dependent data will be described later in detail.

In addition, the dynamic programming processor 303 includes the optimization result combiner 306 for the partial axis-dependent data as a means for combining the optimization results of the partial problems. The optimization result combiner 306 for the partial axis-dependent data expands and combines the partial axis-dependent data to generate optimal divided axis-dependent data. The optimization result combiner 306 for the partial axis-dependent data optimizes the partial axis-dependent data generated by dividing the axis-dependent data by the partial divider 305 of the above-described axis-dependent data by expanding the partial axis-dependent data by one point in each of the positive direction and the negative direction of each axis such as the X axis and the Y axis. The generation of the optimal divided axis-dependent data by the optimization result combiner 306 for the partial axis-dependent data will be described later in detail.

Hereinafter, the division of the axis-dependent data by the dynamic programming processor 303 will be described in detail with reference to FIGS. 16, 17, and 19.

As shown in FIG. 16, the axis-dependent data is divided into, for example, a grid of 15×15=225 points. When such axis-dependent data are divided into sections by the dynamic programming processor 303, for example, divided axis-dependent data as shown in FIG. 17 are obtained. In the division into sections of the axis-dependent data by the dynamic programming processor 303, an approximation error of each error amount in a case where each region of the divided sections is approximated by the above-described approximation model is set to fall within a constraint allowable amount. Further, each of the points at which the approximation error does not fall within the constraint allowable amount is allowed up to the constraint allowable number. Nevertheless, the points that cannot be approximated or do not meet the constraint are minimized in number. As a result, for example, the number of data points 225 can be compressed to 92 points, and the data size can be reduced.

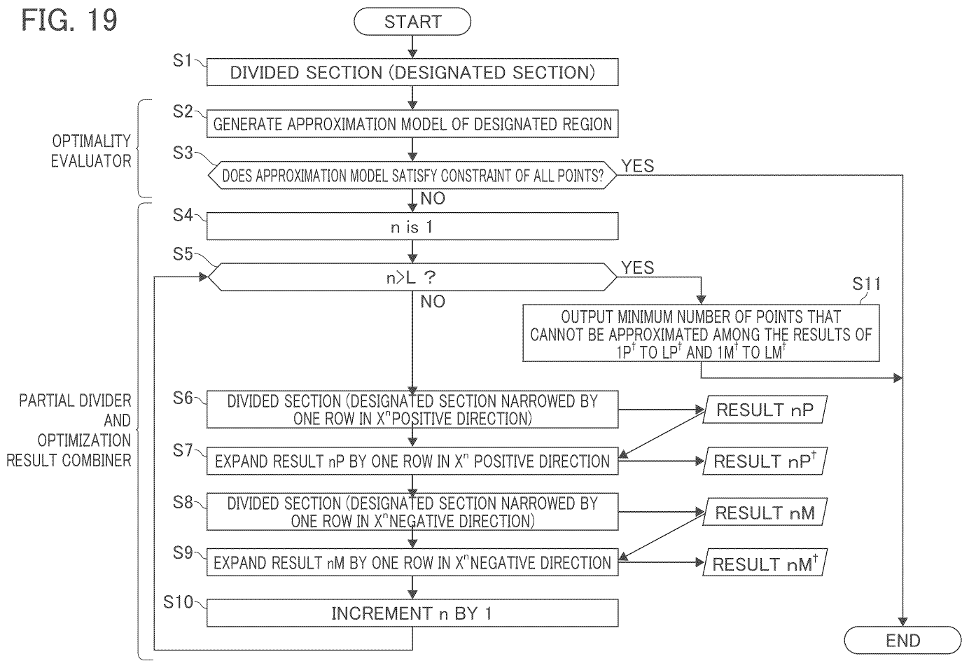

FIG. 19 is a flowchart showing a procedure of dividing the axis-dependent data by the dynamic programming processor 303. The division of the axis-dependent data by the dynamic programming processor 303 is executed by recursively searching for optimal divided sections of the axis-dependent data by the dynamic programming method.

In Step S1, the axis-dependent data is divided into predetermined designated sections. However, in a case of a region in which the division processing of the axis-dependent data has been performed by the dynamic programming processor 303, the held processing result may be reflected in this step. Thereafter, the processing proceeds to Step S2.

In Step S2, an approximation model of each of the regions of the designated sections (designated regions) divided in Step S1 is generated. Specifically, an approximation model (vectors Ea[X₁] . . . [X_{L}]) as a linear combination model described in the first embodiment is generated for each designated region. Thereafter, the processing proceeds to Step S3.

In Step S3, it is determined whether the approximation models of the designated regions generated in Step S2 satisfy the constraint of all points. Examples of the constraint include whether the approximation errors of all points are within the allowable value, and whether the number of points at which the approximation errors are not within the allowable value is within the allowable number of points. When it is determined as YES, it is determined that the axis-dependent data has been optimally divided and optimally divided axis-dependent data has been obtained, and the processing is ended. On the other hand, if it is determined as NO, the processing proceeds to Step S4.

In Step S4, n is set to the initial value 1. Here, the value of n represents each axis and, for example, in a case where the axis configuration is a total of the two axes of the X axis and the Y axis, the value of n represents the X axis when n is 1, and the value of n represents the Y axis when n is 2. Thereafter, the processing proceeds to Step S5.

In Step S5, it is determined whether n is larger than L. Here, L is the number of axes in the designated section of the axis-dependent data. For example, in a case of the two axes of the X axis and the Y axis, L is 2. When it is determined as YES, the processing proceeds to Step S11. On the other hand, if it is determined as NO, the processing proceeds to Step S6.

The processing of Steps S6 to S10 is a case where n is equal to or less than L, and when the number of axes is the two axes of the X axis and the Y axis, and when n is 1, it indicates processing for the X axis, and when n is 2, it indicates processing for the Y axis.

In Step S6, the axis-dependent data is divided into designated sections in which data of each axis (each axis error) is narrowed by one row in the Xⁿ positive direction from the designated sections of Step S1. That is, a new divided section is executed in which data of each axis (each axis error) is reduced by one row in the Xⁿ positive direction. The Xⁿ positive direction indicates the X-axis positive direction when n is 1. The result is outputted as an optimization result nP. When n is 1, the optimization result 1P is outputted. Thereafter, the processing proceeds to Step S7.

In Step S7, the optimization result nP obtained in Step S6 is expanded in the Xⁿ positive direction by one row of data of each axis (each axis error). The result is outputted as an optimization result nP⁺. When n is 1, the optimization result 1P⁺ is outputted. Since n can be in the range of 1 to L, the optimization results 1P to LP⁺ can be obtained by this step. Thereafter, the processing proceeds to Step S8.

In Step S8, the axis-dependent data is divided into designated sections in which the data of each axis (each axis error) is narrowed by one row in the Xⁿ negative direction from the designated sections in Step S1. That is, a new divided section is executed which is reduced by one row of data of each axis (each axis error) in the negative Xⁿ direction. The Xⁿ negative direction indicates the X-axis negative direction when n is 1. The result is outputted as an optimization result nM. When n is 1, the optimization result 1M is outputted. Thereafter, the processing proceeds to Step S9.

In Step S9, the optimization result nM obtained in Step S8 is expanded in the Xⁿ negative direction by one row of data of each axis (each axis error). The result is outputted as an optimization result nM⁺. When n is 1, the optimization result 1M⁺ is outputted. Since n can be in the range of 1 to L, this step results in optimization results 1M to LM⁺. Thereafter, the processing proceeds to Step S10.

In Step S10, n is incremented by 1. Thereafter, the processing returns to Step S5.

In addition, Step S11 is processing when n is larger than L, and when the number of axes is two axes, i.e., the X axis and the Y axis, Step S11 is performed after the processing for the X axis and the Y axis is completed in Steps S6 to S10. In Step S11, among the optimization results 1P to LP⁺ and 1M to LM⁺ obtained in Steps S6 to S10, those having the smallest number of points that cannot be approximated are outputted. That is, for each of the optimization results 1P to LP⁺ and 1M to LM⁺, the number of points that cannot be approximated for which the approximation model generated in Step S3 does not satisfy the above-described constraint is calculated, and those having the minimum number of points that cannot be approximated, approximated best, and compressed most are obtained, and then the processing is ended.

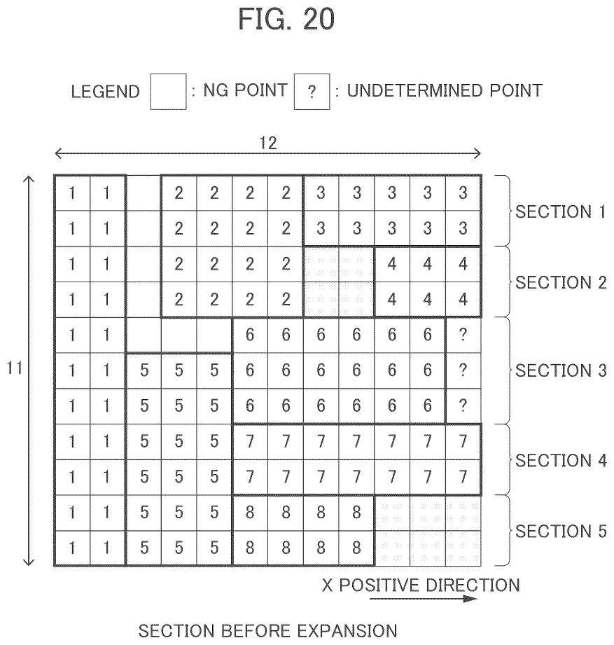

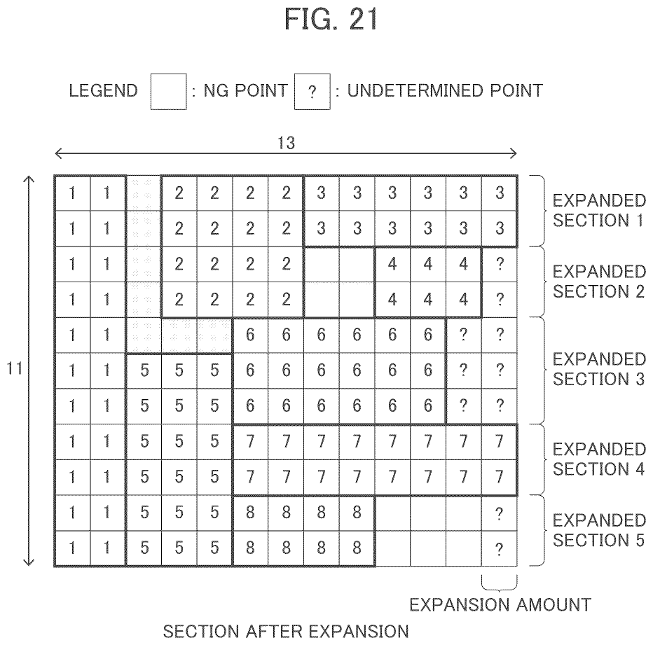

Here, the procedure of expanding one row of data of each axis (each axis error) in the X positive direction in the above-described Step S7 will be described in more detail with reference to the specific examples shown in FIGS. 20 and 21. FIG. 20 is a diagram showing divided sections before expanding data of each axis (each axis error) by one row in the X positive direction. In addition, FIG. 21 is a diagram showing divided sections after expanding the data of each axis (each axis error) by one row in the X positive direction. In FIGS. 20 and 21, different numbers are assigned to the respective divided sections.

As shown in FIG. 20, first, sections 1 to 5 are extracted as continuous sections that appear at the end portion in the X positive direction of the sections before expansion by one row of data of each axis (each axis error).

Then, each of the extracted sections 1 to 5 is expanded by one row of data of each axis (each axis error) to generate expanded sections 1 to 5, as shown in FIG. 21.

Next, for each of the expanded sections 1 to 5, it is checked whether the above-described approximation model satisfies the above-described constraint. If the constraint is satisfied, the expanded sections are set as the new sections. In the example shown in FIG. 21, since the expanded sections 1 and 4 satisfy the constraint, they are set as new sections.

If the constraint is not satisfied, the sections of the expansion amount are set as undetermined sections. In the example shown in FIG. 21, since the expanded section 2 does not satisfy the constraint, it is set as an undetermined section.

When each of the undetermined sections is equal to or larger than a predetermined area (for example, 2×2), it is checked whether the above-described approximation model satisfies the above-described constraint. In the example shown in FIG. 21, since the expanded section 3 is equal to or larger than a predetermined area (for example, 2×2), this determination is performed. Until then, this expanded section is also determined as an undetermined section.

In addition, in a case where the section before expansion is an NG section, that is, a section that does not satisfy the constraint and cannot be approximated, the section of the expansion amount is an undetermined section. In the example shown in FIG. 21, since the expanded section 5 corresponds to the NG section, it is set as an undetermined section.

As described above, there is a case where an undetermined section remains until the end. Such a section may finally be an NG section, that is, a section that does not satisfy the constraint and cannot be approximated.

As described above, according to the data encoding device 30, since the axis-dependent data can be divided into the optimal divided axis-dependent data that can be compressed while reducing the number of pieces of data to the most, it is possible to generate an optimal plurality of regions that can each be regarded as a linear combination of data of each axis (each axis error), and by executing the model approximation encoding of the linear combination model for each region, it is possible to further compress the axis-dependent data, which has been difficult to compress conventionally.

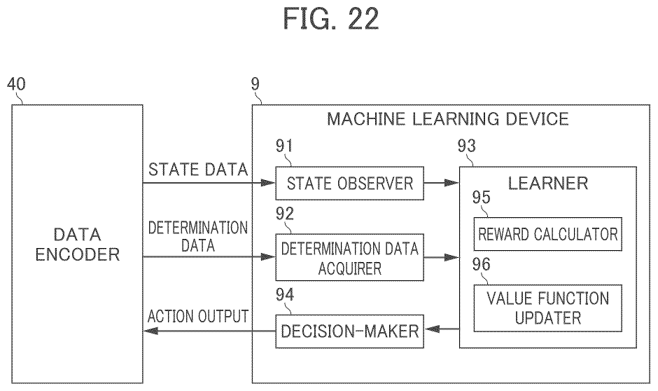

FIG. 22 is a diagram showing the configuration of a data encoding device 40 in a third modification example of the approximation error detection device according to the first embodiment. As shown in FIG. 22, the data encoding device 40 differs from the data encoding device 30 in that the data encoding device 40 includes a learning result acquirer that acquires a reinforcement learning result by a machine learning device 9 instead of the dynamic programming method, and the axis-dependent data is divided into segments using the learning result. The configurations of the data encoding device 40 other than these differences are the same as those of the data encoding device 30.

The machine learning device 9 performs reinforcement learning for optimal division processing of axis-dependent data. In reinforcement learning by the machine learning device 9 according to the present embodiment, when the machine learning device 9 as an agent acquires axis-dependent data such as an error amount of an industrial machine as a state of an environment, and selects divided axis-dependent data as an action, the environment changes based on the action. As the environment changes, the number of points that cannot be approximated and the amount of data after approximation obtained by performing model approximation encoding on the divided axis-dependent data are obtained as determination data. Then, some reward is given according to the obtained determination data, and the machine learning device 9 as an agent selects a better action, i.e., learns the divided axis-dependent data optimal for decision making. The machine learning device 9 as an agent learns to select an action that maximizes the sum of rewards in the future.

Any learning method can be used for reinforcement learning. For example, Q learning, which is a method of learning a value Q(s, a) for selecting a certain action a under a certain state s of a certain environment, can be used. In the Q learning, in a certain state s, an action a having the highest value Q(s, a) is selected as an optimal action from among possible actions a. However, the correct value of the value Q(s, a) is not known at all for the combination of the state s and the action a at the time when the Q learning is started first. Therefore, the machine learning device 9 as an agent selects various actions a under a certain state s, and learns a correct value Q(s, a) by selecting a better action based on a reward given to the action a at that time.

In addition, in order to maximize the sum of rewards obtained in the future, the machine learning device 9 aims to finally obtain Q(s, a)=E[Σ(γ^{t})rₜ]. Here, E[ ] represents an expected value, t is a time, γ is a parameter of a discount rate to be described later, rₜ is a reward at the time t, and Σ is a total at the time t. The expected value in this expression is an expected value when the state is changed according to the optimal action. However, since it is unknown what the optimal action is in the process of Q-learning, reinforcement learning is performed while searching for various actions. Such an update expression of the value Q(s, a) can be expressed by, for example, the following Expression (11).

$$\begin{matrix}[ Expression 11 ] & \\ Q ( {s}_{t + 1} , {a}_{t + 1} ) ← Q ( {s}_{t} , {a}_{t} ) + α ( {r}_{t + 1} + γ {max}_{a} Q ( {s}_{t + 1} , a ) - Q ( {s}_{t} , {a}_{t} ) ) & Expression ( 11 )\end{matrix}$$

In Expression (11), sₜ represents the state of the environment at time t, and at represents the action at time t. The state is changed to sₜ₊₁ by the action at. The term rₜ₊₁ represents a reward obtained by a change in the state. The term with max is obtained by multiplying, by γ, the Q value in a case where the action a having the highest Q value known at that time is selected under the state sₜ₊₁. Here, γ is a parameter of 0<γ≤1, and is referred to as a discount rate. Further, a is a learning coefficient, and is in a range of 0≤α≤1.

Expression (11) above represents a method of updating the value Q(sₜ, aₜ) of the action aₜ in the state sₜ based on the reward rₜ₊₁ returned as a result of the trial aₜ. This update expression indicates that, if the value maxₐ Q(sₜ₊₁, a) of the best action in the next state sₜ₊₁ by the action aₜ is larger than the value Q (sₜ, aₜ) of the action aₜ in the state sₜ, Q (sₜ, aₜ) is increased, and if it is smaller, Q(sₜ, aₜ) is decreased. That is, the value of a certain action in a certain state is made closer to the value of the best action in the next state. However, although the difference varies depending on the discount rate γ and the reward rₜ₊₁, basically, the value of the best action in a certain state propagates to the value of the action in the immediately preceding state.

Here, in the Q learning, there is a method of creating a table of Q(s, a) for all the state action pairs (s, a) and performing learning. However, there is a case where the number of states is too large to obtain the values of Q(s, a) of all the state action pairs, and it would take a long time for the Q learning to converge.

Therefore, a known technique called Deep Q-Network (DQN) may be used. Specifically, the value function Q may be configured using an appropriate neural network, parameters of the neural network may be adjusted, and the value function Q may be approximated with an appropriate neural network, such that the value of the value Q(s, a) is calculated. By using the DQN, it is possible to shorten the time required for the Q-learning to converge. The DQN is described in detail in, for example, the Non-patent Document of “Human-level control through deep reinforcement learning”, Volodymyr Mnihl, [online], [searched on Jan. 17, 2017], the Internet <URL: http://files.davidqiu.com/research/nature14236.pdf>.

Therefore, in order to execute the reinforcement learning described above, the machine learning device 9 includes a state observer 91, a determination data acquirer 92, a learner 93, and a decision-maker 94, as shown in FIG. 22. The learner 93 includes a reward calculator 95 and a value function updater 96.

The state observer 91 acquires axis-dependent data as state data from the data encoding device 7. In addition, the state observer 91 outputs the acquired axis-dependent data to the learner 93.

The determination data acquirer 92 acquires, as determination data from the data encoding device 7, the number of points that cannot be approximated and the approximated data amount obtained by performing model approximation encoding on the divided axis-dependent data. The divided axis-dependent data is obtained by dividing the axis-dependent data into predetermined designated sections in accordance with a predetermined division criterion stored in advance. In addition, the determination data acquirer 92 outputs the acquired number of points that cannot be approximated and the approximated data amount to the learner 93.

The reward calculator 95 of the learner 93 calculates a reward based on the acquired axis-dependent data, the number of points that cannot be approximated and the approximated data amount. Specifically, the reward calculator 95 increases the reward when the number of points that cannot be approximated decreases, and decreases the reward when the number of points that cannot be approximated increases. In addition, the reward calculator 95 increases the reward when the approximated data amount decreases, and decreases the reward when the approximated data amount increases.

The value function updater 96 of the learner 93 updates the stored value function by performing the above-described Q learning based on the axis-dependent data as the state data, the number of points that cannot be approximated and the approximated data amount obtained by performing the model approximation encoding on the divided axis-dependent data as the determination data, and the value of the reward. In addition, the value function stored in the value function updater 96 can be shared by a plurality of machine learning devices communicably connected to each other, for example.

The decision-maker 94 acquires the updated value function from the value function updater 96. In addition, the decision-maker 94 outputs the optimal divided axis-dependent data as an action output to the data encoding device 40 based on the acquired value function.

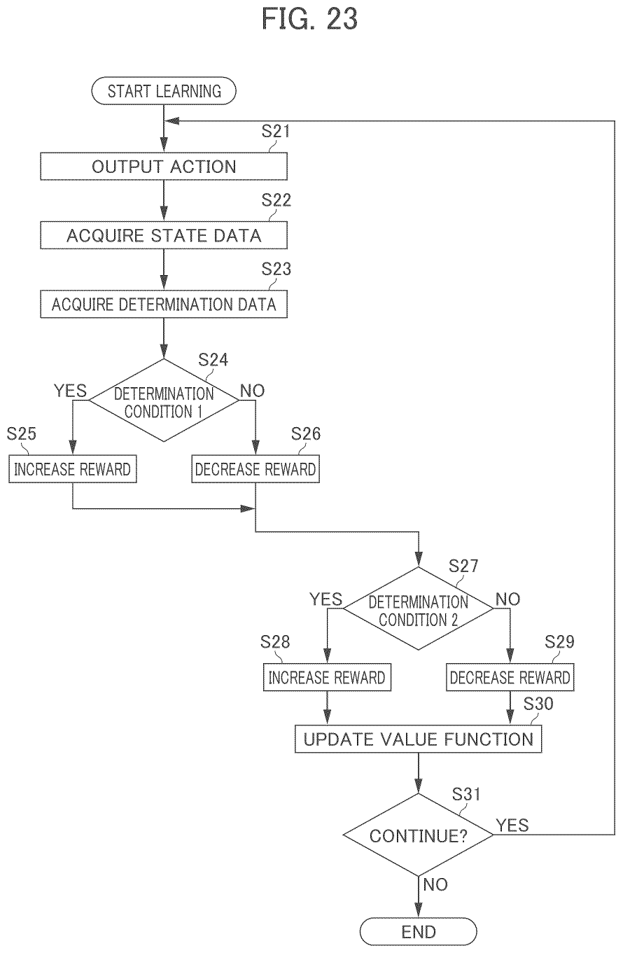

FIG. 23 is a flowchart showing a procedure of learning processing by the machine learning device 9.

In Step S21, first, the machine learning device 9 outputs the divided axis-dependent data as an action output to the data encoding device 40. The divided axis-dependent data outputted in this step is obtained by dividing the axis-dependent data into predetermined designated sections in accordance with a predetermined division criterion stored in advance. The data encoding device 40 performs model approximation encoding on the divided axis-dependent data to generate the number of points that cannot be approximated and the approximated data amount. Thereafter, the processing proceeds to Step S22.

In Step S22, the machine learning device 9 acquires axis-dependent data as state data from the data encoding device 40. Thereafter, the processing proceeds to Step S23.

In Step S23, the machine learning device 9 acquires, as determination data from the data encoding device 40, the number of points that cannot be approximated and the approximated data amount after model approximation encoding of the divided axis-dependent data generated in Step S21. Thereafter, the processing proceeds to Step S24.

In Step S24, as a determination condition 1, it is determined whether the number of points that cannot be approximated when the data encoding device 40 performs model approximation encoding on the divided axis-dependent data has decreased. If it is determined as YES, the processing proceeds to Step S25, where the reward is increased. On the other hand, if it is determined as NO, the processing proceeds to Step S26, where the reward is reduced. Thereafter, the processing proceeds to Step S27.

In Step S27, as a determination condition 2, it is determined whether the amount of data after the model approximation encoding when the model approximation encoding is performed on the divided axis-dependent data by the data encoding device 40 is decreased. If it is determined as YES, the processing proceeds to Step S28, where the reward is increased. On the other hand, if it is determined as NO, the processing proceeds to Step S29, where the reward is decreased. Thereafter, the processing proceeds to Step S30.

In Step S30, the value function stored in the value function updater 96 is updated. Specifically, the value function updater 96 updates the stored value function by performing the above-described Q-learning based on the axis-dependent data as the state data, the number of points that cannot be approximated and the approximated data amount obtained by performing the model approximation encoding on the divided axis-dependent data as the determination data, and the value of the reward. Thereafter, the processing proceeds to Step S31.

In Step S31, it is determined whether to continue the present learning process. When it is determined as YES, the processing returns to Step S21. On the other hand, if it is determined as NO, the present processing is ended.

As described above, according to the data encoding device 40, since the axis-dependent data can be divided into the optimal divided axis-dependent data that can be compressed while reducing the number of data by the reinforcement learning by the machine learning device 9, it is possible to generate an optimal plurality of regions that can be regarded as the linear combination of data of each axis (each axis error), and by performing the model approximation encoding of the linear combination model for each region, it is possible to further compress the axis-dependent data, which has conventionally been difficult to compress.

In the present modification example, the machine learning device 9 is provided separately from the data encoding device 40, but the present invention is not limited thereto, and a machine learning device may be provided inside the data encoding device 40.

In the first embodiment described above, it is also possible to provide a data encoding program for causing the approximation error detection device 1 to execute processing. That is, it is also possible to provide an approximation error detection program for detecting an approximation error, the approximation error detection program causing a computer to execute a step of detecting, based on a portion of axis-dependent data depending on coordinate values of each axis of an industrial machine and a linear combination model that approximates the axis-dependent data as a linear combination of data of each axis of the industrial machine, an approximation error amount having an absolute value equal to or greater than a predetermined threshold value, from among approximation error amounts obtained by performing model approximation encoding on the axis-dependent data.

### Second Embodiment

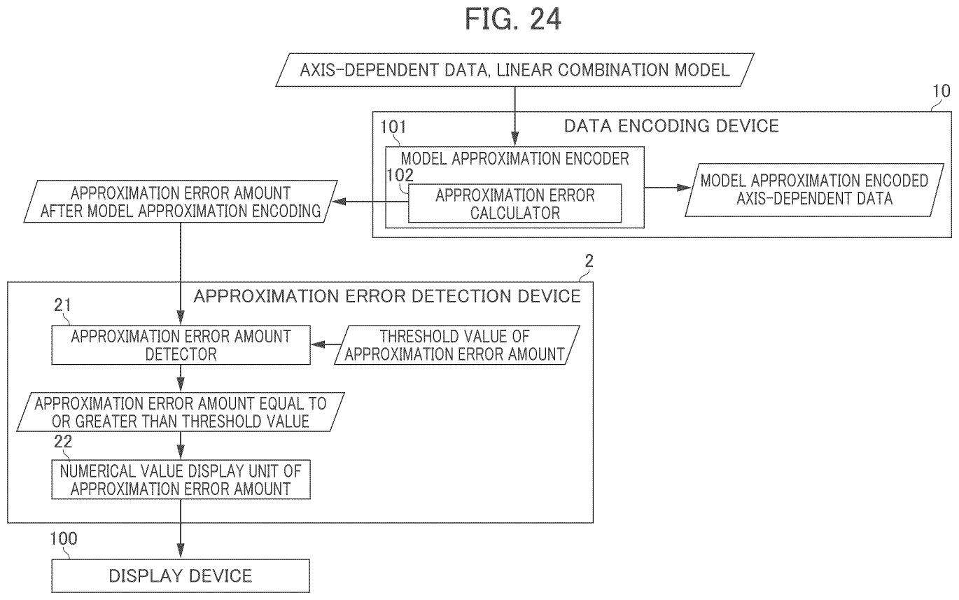

FIG. 24 is a diagram showing the configuration of an approximation error detection device 2 according to a second embodiment. As shown in FIG. 24, the approximation error detection device 2 of the present embodiment differs from the approximation error detection device 1 of the first embodiment in that the approximation error detection device 2 includes a numerical value display unit 22 of the approximation error amount. In addition, the display device 100 is communicably connected to the approximation error detection device 2 of the present embodiment. The approximation error detection device 2 of the present embodiment is the same as the approximation error detection device 1 of the first embodiment except for this difference.

The numerical value display unit 22 of the approximation error amount acquires an approximation error amount equal to or larger than a predetermined threshold value detected by the approximation error amount detector 21. Further, the numerical value display unit 22 of the approximation error amount displays the approximate error amount as a numerical value on the display screen of the display device 100 by outputting the acquired approximation error amount equal to or larger than the predetermined threshold value to the display device 100.

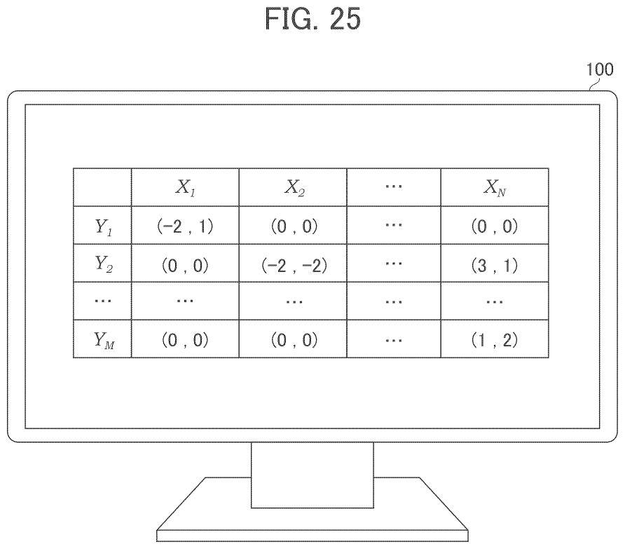

Here, FIG. 25 is a diagram showing an example of numerical value display of the approximation error amount when the threshold value is 0. In the example shown in FIG. 25, since the threshold value is 0, all of the approximation error amounts when the axis-dependent data depending on the coordinate values of each axis of the industrial machine is approximated and encoded are displayed on the display screen of the display device 100.

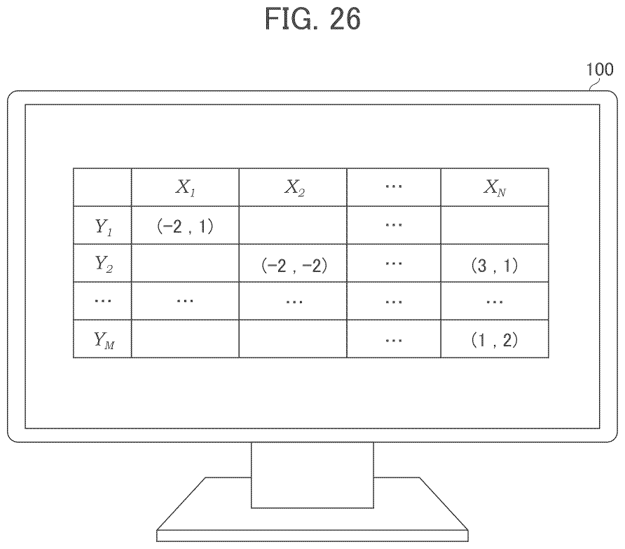

FIG. 26 is a diagram showing a first example of numerical value display of the approximation error amount when the absolute value of the threshold is greater than 0. In the example shown in FIG. 26, since the absolute value of the threshold is a value larger than 0, it is evident, as compared with FIG. 25, that the display of the coordinates of the approximation error amount (0, 0) is not displayed. In this way, the numerical value display unit 22 can display only the approximation error amounts equal to or larger than the threshold value.

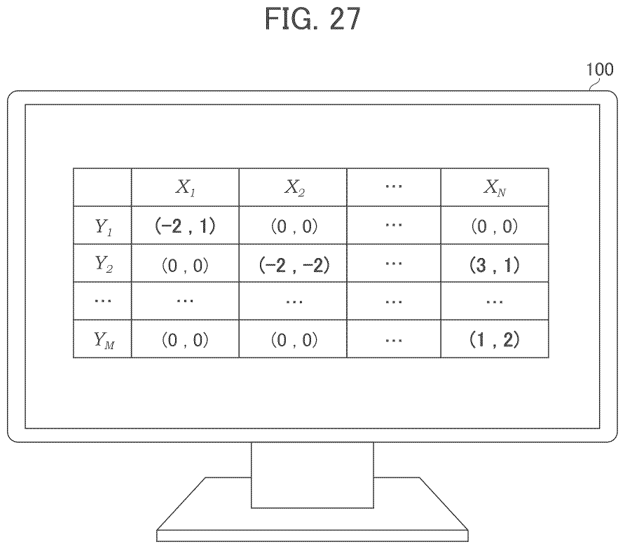

FIG. 27 is a diagram showing a second example of numerical value display of the approximation error amount when the absolute value of the threshold is greater than 0. In the example shown in FIG. 27, since the absolute value of the threshold is a value larger than 0, it is evident, as compared to FIG. 25, that the display of the coordinates other than the approximation error amount (0, 0) is highlighted in bold text. The method of highlighting is not particularly limited, and in addition to bold text, various methods such as markers, hatching, enlargement of displayed characters, and color coding can be employed. In this way, the numerical value display unit 22 can highlight only the approximation error amounts equal to or larger than the threshold value as numerical values.

According to the present embodiment, the following advantageous effects are achieved.

The approximation error detection device 2 of the present embodiment further includes the numerical value display unit 22 that displays the approximation error amount detected by the approximation error amount detector 21 as a numerical value. Thus, the user of the industrial machine can easily visually grasp the approximation error amount equal to or larger than the threshold value displayed as a numerical value on the display device 100.

### Third Embodiment

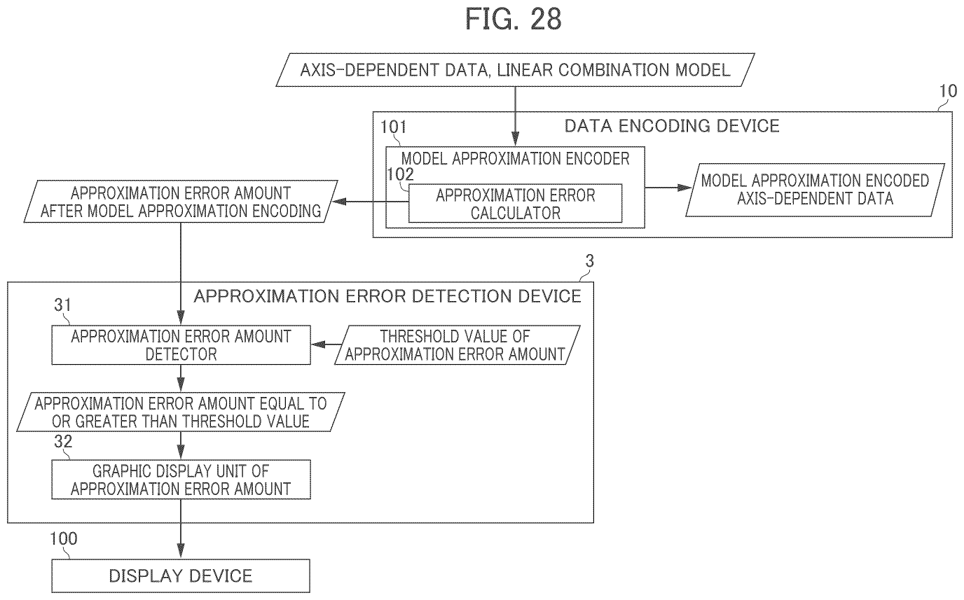

FIG. 28 is a diagram showing the configuration of an approximation error detection device 3 according to a third embodiment. As shown in FIG. 28, the approximation error detection device 3 of the present embodiment differs from the approximation error detection device 1 of the first embodiment in that the approximation error detection device 3 includes a graphic display unit 32 of the approximation error amount. Further, the display device 100 is communicably connected to the approximation error detection device 3 of the present embodiment. The approximation error detection device 3 of the present embodiment is the same as the approximation error detection device 1 of the first embodiment except for this difference.

The graphic display unit 32 of the approximation error amount acquires an approximation error amount equal to or larger than a predetermined threshold detected by the approximation error amount detector 31. Further, the graphic display unit 32 of the approximation error amount displays the approximation error amount on the display screen of the display device 100 as graphics by outputting the acquired approximation error amount equal to or larger than the predetermined threshold to the display device 100.

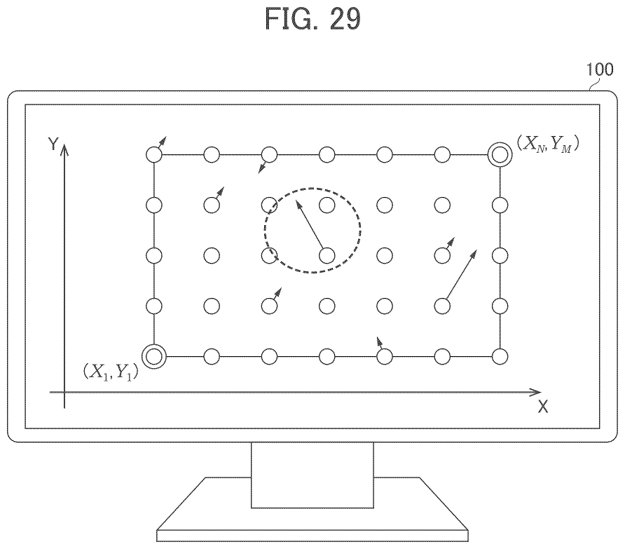

Here, FIG. 29 is a diagram showing an example of a graphic display of the approximation error amount when the threshold value is 0. In the example shown in FIG. 29, since the threshold value is 0, all of the approximation error amounts when the axis-dependent data depending on the coordinate values of each axis of the industrial machine is approximated and encoded are displayed on the display screen of the display device 100 as graphics. More specifically, as shown in FIG. 29, the approximation error amount is displayed by the direction and length of an arrow.

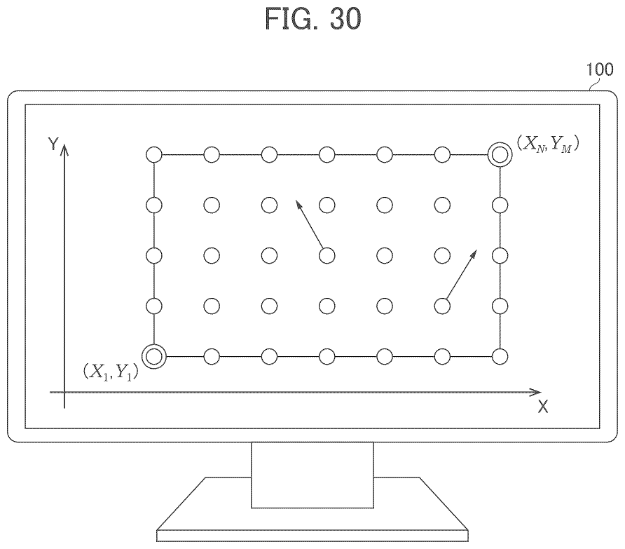

Further, FIG. 30 is a diagram showing a first example of the graphic display of the approximation error amount when the absolute value of the threshold is greater than 0. In the example shown in FIG. 30, since the absolute value of the threshold is a value larger than 0, it is evident, as compared with FIG. 29, that the arrow display of the coordinates of the approximation error amount (0, 0) is not displayed. In this way, the graphic display unit 32 can display only the approximation error amount equal to or larger than the threshold.

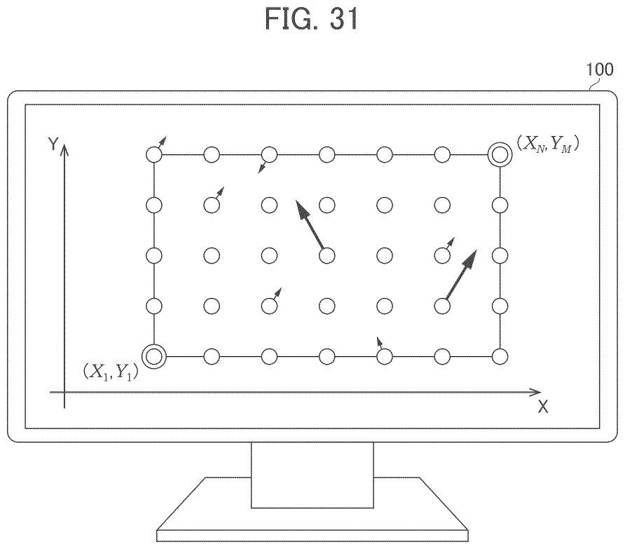

FIG. 31 is a diagram showing a second example of the graphic display of the approximation error amount when the absolute value of the threshold is greater than 0. In the example shown in FIG. 31, since the absolute value of the threshold is a value larger than 0, it is evident, as compared to FIG. 29, that the arrow display of the coordinates other than (0, 0) of the approximation error amount are highlighted in bold text. The highlighting method is not particularly limited, and in addition to bold text, various methods such as markers, hatching, enlargement of display, and color coding can be employed. In this way, the graphic display unit 32 can highlight only the approximation error amount equal to or larger than the threshold value as graphics.

According to the present embodiment, the following advantageous effects are achieved.

The approximation error detection device 3 of the present embodiment further includes the graphic display unit 32 that displays the approximation error amount detected by the approximation error amount detector 31 as graphics. With such a configuration, the user of the industrial machine can easily visually grasp the approximation error amount equal to or larger than the threshold value displayed on the display device 100 as graphics.

It should be noted that the present disclosure is not limited to the above-described embodiments, and modifications and improvements within a scope in which the object of the present disclosure can be achieved are included in the present disclosure.

In each of the above-described embodiments, each model approximation encoder is configured to include the approximation error calculator. However, for example, a configuration may be adopted in which the model approximation encoded axis-dependent data encoded by each of the data encoding devices is decoded by the data decoding device, and the approximation error amount is calculated based on the difference between the decoded axis-dependent data and the original axis-dependent data.

### EXPLANATION OF REFERENCE NUMERALS

1, 2, 3 approximation error detection device
9 machine learning device
10, 20, 30, 40 data encoding device
11, 21, 31 approximation error amount detector
22 numerical value display unit of approximation error amount (numerical value display unit)
32 graphic display unit of approximation error amount (graphic display unit)
100 display device
101, 201, 301 model approximation encoder
102 approximation error calculator
202, 302 axis-dependent data divider
303 dynamic programming processor
304 optimality evaluator after model approximation encoding
305 partial divider of axis-dependent data
306 optimization result combiner of partial axis-dependent data

1. An approximation error detection device that detects an approximation error, the approximation error detection device comprising
an approximation error amount detector that detects, based on a portion of axis-dependent data depending on coordinates of each axis of an industrial machine and a linear combination model that approximates the axis-dependent data as a linear combination of data of each axis of the industrial machine, an approximation error amount having an absolute value equal to or greater than a predetermined value, from among approximation error amounts obtained by performing model approximation encoding on the axis-dependent data.

2. The approximation error detection device according to claim 1, further comprising a numerical value display unit that displays an approximation error amount detected by the approximation error amount detector as a numerical value.

3. The approximation error detection device according to claim 1, further comprising a graphic display unit that displays an approximation error amount detected by the approximation error amount detector as graphics.

4. A non-transitory computer-readable medium storing an approximation error detection program for detecting an approximation error, the non-transitory computer-readable medium storing the program causing a computer to execute a step of detecting, based on a portion of axis-dependent data depending on coordinates of each axis of an industrial machine and a linear combination model that approximates the axis-dependent data as a linear combination of data of each axis of the industrial machine, an approximation error amount having an absolute value equal to or greater than a predetermined value, from among approximation error amounts obtained by performing model approximation encoding on the axis-dependent data.
